(19) United States
(12) Patent Application Publication
(10) Pub. No.: US 2010/0018758 A1
(43) Pub. Date: Jan. 28, 2010

(54) PRINTED WIRING BOARD

(75) Inventors: Hideaki Yoshimura, Kawasaki (JP); Norikazu Ozaki, Kawasaki (JP); Kenji Iida, Kawasaki (JP); Tomoyuki Abe, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/486,996

(22) Filed: Jun. 18, 2009

(30) Foreign Application Priority Data
Jul. 28, 2008 (JP) 2008-193394

(51) Int. Cl. H05K 1/03

(52) U.S. Cl. 174/256; 174/124 G

(57) ABSTRACT

A printed wiring board which includes a core substrate and a plurality of buildup layer. The core substrate contains carbon fiber. The plurality of buildup layers is stacked on the core substrate. The buildup layer includes an insulating layer and a conductive wiring layer. The insulating layer contains a resin material having a glass fiber cloth embedded therein.

### CROSS-REFERENCE TO RELATED APPLICATION

This application is based upon and claims the benefit of priority of the prior Japanese Patent Application No. 2008-193394, filed on Jul. 28, 2008, the entire contents of which are incorporated herein by reference.

### FIELD

The present invention relates to a printed wiring board.

### BACKGROUND

A printed wiring board includes a core substrate containing, for example, carbon fiber. The core substrate has sufficient rigidity to maintain the stand-alone shape. A buildup layer is formed in a laminated structure on the front surface and/or the back surface of the core substrate. The buildup layer includes an insulating layer and a conductive wiring layer which are alternately stacked. The insulating layer is formed of resin material (see, for example, Japanese Laid-Open Patent Application No. 2004-87856).

The coefficient of thermal expansion of the conductive wiring layer in a buildup layer is significantly different from that of the core substrate. As a result, a large stress may be concentrated in an interface between the conductive wiring layer and the insulating layer. Based on such a stress, cracks may occur in the conductive wiring layer and/or insulating layer to cause a wiring disconnection in the conductive wiring layer.

### SUMMARY

According to an aspect of the invention, a printed wiring board includes a core substrate and a plurality of buildup layer. The core substrate contains carbon fiber. The plurality of buildup layers is stacked on the core substrate. The buildup layer includes an insulating layer and a conductive wiring layer. The insulating layer contains a resin material having a glass fiber cloth embedded therein.

It is to be understood that both the foregoing general description and the following detailed description are exemplary, and do not restrict the invention as claimed.

### BRIEF DESCRIPTION OF DRAWINGS

The above and other objects, features and advantages of the present invention will become apparent from the following description of the embodiments in conjunction with the accompanying drawings, wherein:

FIG. 1 schematically illustrates a cross-sectional structure of a printed wiring board according to a first embodiment of the present invention;

FIG. 2 is an enlarged partial sectional view of a buildup layer;

FIG. 3 illustrates a process to stack conductive wiring layers on a back surface of a resin sheet;

FIG. 4 illustrates a process to form a through-hole in the resin sheet;

FIG. 5 illustrates a process to perform electroless plating on a front surface of the resin sheet;

FIG. 6 illustrates a process to perform electrolytic plating on the front surface of the resin sheet;

FIG. 7 illustrates a process to remove a photoresist from the front surface of the resin sheet;

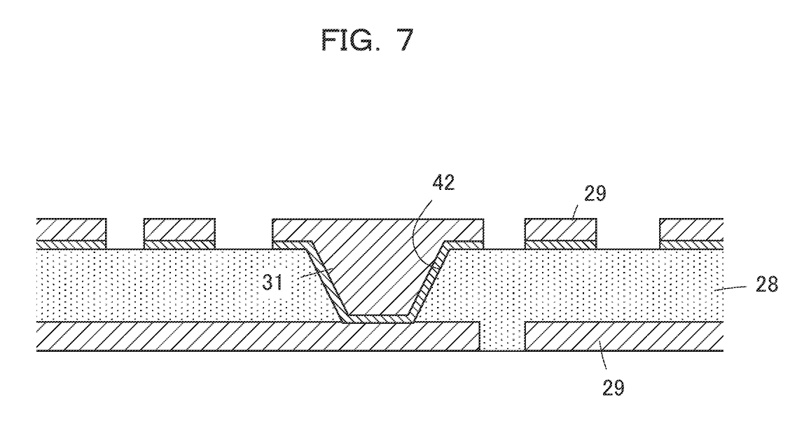

FIG. 8 illustrates a process to laminate the buildup layers on a core substrate;

FIG. 9 illustrates the cross-sectional structure of a printed wiring board according to a second embodiment of the present invention;

FIG. 10 is an enlarged sectional view of the buildup layer;

FIG. 11 illustrates a process to stack conductive wiring layers on the back surface of a first resin sheet;

FIG. 12 illustrates a process to stack a second resin sheet on the front surface of the first resin sheet;

FIG. 13 illustrates a process to perform electroless plating on the front surface of a laminated body while a through-hole is formed in the laminated body of the resin sheet;

FIG. 14 illustrates a process to form a photoresist on the front surface of the laminated body;

FIG. 15 illustrates a process to perform a plating process on the front surface of the laminated body; and

FIG. 16 illustrates a process to remove the photoresist from the front surface of the laminated body.

### DESCRIPTION OF EMBODIMENTS

Hereinafter, embodiments of the present invention will be described with reference to the attached drawings.

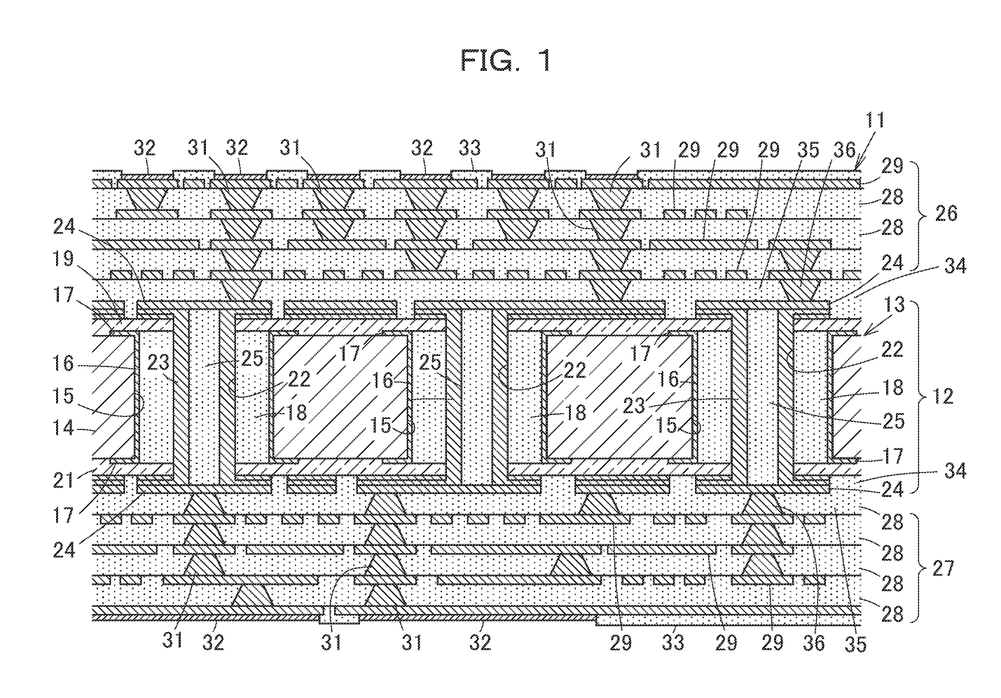

FIG. 1 illustrates the cross-sectional structure of a printed wiring board 11 according to the first embodiment of the present invention. The printed wiring board 11 may be used as a probe card. The probe card is mounted in an electronic device such as a probe device. Alternatively, the printed wiring board 11 may be used in other electronic devices.

The printed wiring board 11 includes a core substrate 12. The core substrate 12 has sufficient rigidity to maintain the stand-alone shape. The core substrate 12 includes a flat core layer 13. The flat core layer 13 includes a conductive layer 14. A carbon fiber cloth is embedded in the conductive layer 14. The fiber of the carbon fiber cloth extends in an in-plane direction of the core layer 13. Therefore, thermal expansion in the in-plane direction is suppressed in the conductive layer 14. The carbon fiber cloth has conductivity. The carbon fiber cloth is impregnated with a resin material when the conductive layer 14 is formed. A heat-curable resin such as epoxy resin may be used as the resin material. The carbon fiber cloth is formed from a woven or nonwoven fabric of carbon fiber threads.

A plurality of prepared through-holes 15 is formed in the core layer 13. The prepared through-hole 15 penetrates through the core layer 13. The prepared through-hole 15 may define a columnar space. The axial center of the cylindrical space is orthogonal to the front surface and the back surface of the core layer 13. Due to the prepared through-hole 15, circular openings are partitioned on the front surface and the back surface of the core layer 13.

A conductive via 16 is formed in the prepared through-hole 15. The via 16 is formed in a cylindrical shape along an inner wall surface of the prepared through-hole 15. The via 16 is connected to an annular conductive land 17 on the front surface and the back surface of the core layer 13. The conductive land 17 extends outward the prepared through-hole 15 on the front surface and the back surface of the core layer 13. The via 16 and the conductive lands 17 may be formed from copper.

An inner space of the via 16 of the prepared through-hole 15 is filled with a prepared filler 18 of resin. The prepared filler 18 is formed in the cylindrical shape along the inner wall surface of the via 16. Heat-curable resin material such as epoxy resin may be used for the prepared filler 18. A ceramic filler may be embedded in epoxy resin.

The core substrate 12 is provided with insulating layers 19 and 21 which are respectively stacked on the front surface and the back surface of the core layer 13. Each of the insulating layers 19 and 21 is attached to the front surface and the back surface of the core layer 13. The core layer 13 is interposed between the insulating layers 19 and 21. The insulating layers 19 and 21 entirely cover the prepared filler 18. A glass fiber cloth is embedded in the respective insulating layers 19 and 21. The fiber of the glass fiber cloth in the insulating layers 19 and 21 extends along the front surface and the back surface of the core layer 13. When the insulating layers 19 and 21 are formed, the glass fiber cloth is impregnated with resin material. Heat-curable resin such as epoxy resin may be used as the resin material. The glass fiber cloth may be formed from one of woven fabric and nonwoven fabric of glass fiber threads.

The core substrate 12 is provided with a plurality of through-holes 22. The through-holes 22 penetrate through the core substrate 12. The through-holes 22 are disposed within the prepared through-holes 15. The prepared filler 18 is penetrated through by the through-hole 22. The through-hole 22 may define a columnar space. The through-hole 22 and the prepared through-hole 15 are coaxial. Due to the through-hole 22, circular openings are partitioned on the front surface and the back surface of the core substrate 12.

A conductive via 23 is formed in the through-hole 22. The via 23 is formed in the cylindrical shape along the inner wall surface of the through-hole 22. Due to the prepared filler 18, the via 16 and the via 23 are insulated from each other. The via 23 may be formed from copper.

Conductive lands 24 are formed on the front surface of the insulating layers 19 and 21. The via 23 is connected to the conductive land 24 on the front surface of the insulating layer 19 or 21. The conductive land 24 may be formed from copper. An inner space of the via 23 between the conductive lands 24 is filled with a filler 25 of insulating resin. The filler 25 may be formed in the columnar shape. Heat-curable resin material such as epoxy resin may be used for the filler 25. A ceramic filler may be embedded in the epoxy resin.

Buildup layers 26 and 27 are formed on the front surface and the back surface of the core substrate 12, respectively. The buildup layers 26 and 27 may have no sufficient rigidity to maintain the stand-alone shape. Each of the buildup layers 26 and 27 is attached to the front surface and the back surface of the core substrate 12. The core substrate 12 is interposed between the buildup layers 26 and 27. A plurality of insulating layers 28 is alternately stacked on a plurality of conductive wiring layers 29 to form the buildup layers 26 and 27. The conductive wiring layers 29 in different layers are electrically connected by vias 31. When a via 31 is formed, a through-hole is formed in the insulating layer 28 between the conductive wiring layers 29. The through-hole is filled with a conductive material. The insulating layer 28 may be formed from heat-curable resin such as epoxy resin. The conductive wiring layer 29 and the via 31 may be formed from copper.

Conductive pads 32 are exposed on the front surfaces of the buildup layers 26 and 27. The conductive pads 32 may be formed from copper. An overcoat layer 33 is coated on the front surfaces of the buildup layers 26 and 27 over a region other than the conductive pads 32. A resin material may be used for the overcoat layers 33.

Joint layers 34 are interposed between the respective buildup layers 26, 27 and the core substrate 12. The joint layer 34 is provided with an insulating body 35. The insulating body 35 may be formed from heat-curable resin such as epoxy resin. A glass fiber cloth may be embedded in the insulating body 35. The conductive wiring layers 29 on the back surface of the buildup layers 26 and 27 are electrically connected to the conductive land 24 of the core substrate 12 by a via 36. When the via 36 is formed, a through-hole is formed in the insulating body 35 between the conductive wiring layer 29 and the conductive land 24. The through-hole is filled with a conductive material. The via 36 may be formed from copper.

The conductive pad 32 on the front surface of the printed wiring board 11 is electrically connected to a conductive pad 32 on the back surface of the printed wiring board 11. When the printed wiring board 11 is mounted in a probe device, a conductive pad 32 on the back surface of the printed wiring board 11 is connected to, for example, an electrode terminal of the probe device. Then, when a semiconductor wafer is mounted on the front surface of the printed wiring board 11, the conductive pad 32 on the front surface of the printed wiring board 11 is connected to, for example, a bump electrode of the semiconductor wafer. In this way, an inspection of the semiconductor wafer may be performed based on, for example, a temperature cycling test.

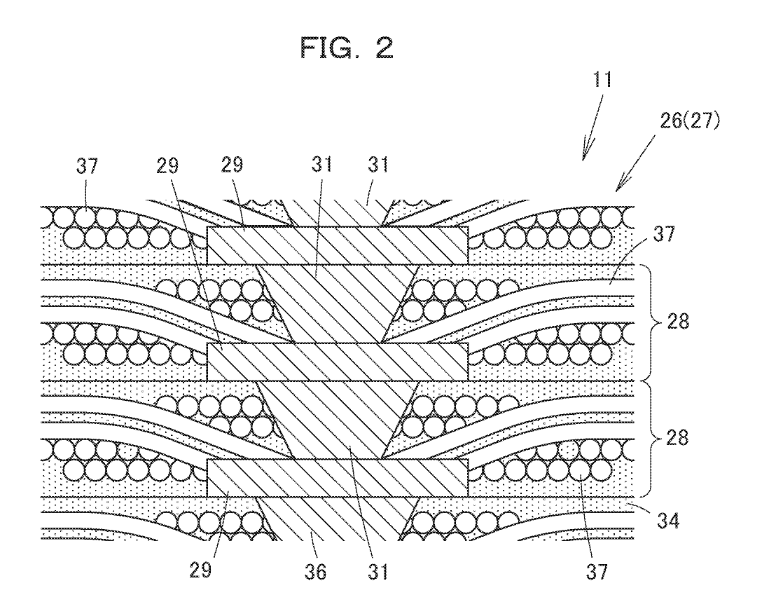

As depicted in FIG. 2, for example, a sheet of the glass fiber cloth 37 is embedded in each insulating layer 28 in the buildup layers 26 and 27. The fiber of the glass fiber cloth 37 extends along the front surface of the insulating layer 28. When the insulating layer 28 is formed, the glass fiber cloth 37 is impregnated with resin material. Heat-curable resin such as epoxy resin is used as the resin material. The glass fiber cloth 37 is formed from one of woven fabric and nonwoven fabric of glass fiber threads. In the embodiment, since the glass fiber cloth 37 is completely embedded within a resin material, exposure of the glass fiber cloth 37 with respect to the front surface and the back surface of the insulating layer 28 may be prevented.

In the printed wiring board 11 described above, the glass fiber cloth 37 is embedded in the insulating layers 28 of the buildup layers 26 and 27. Due to the glass fiber cloth 37, the coefficient of thermal expansion of the buildup layers 26 and 27 is suppressed to be low, and may be accommodated to that of the core substrate 12. Accordingly, the occurrence of a stress within the buildup layers 26 and 27 may be suppressed. Cracks in the buildup layers 26 and 27 may be suppressed. Consequently, a wiring disconnection in the conductive wiring layer 29 may be suppressed.

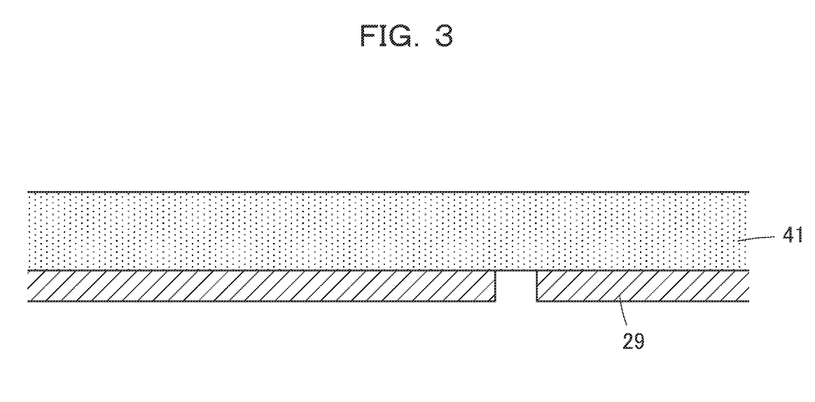

Next, the manufacturing method of the printed wiring board 11 will be described. The core substrate 12 is prepared. Also, the buildup layers 26 and 27 may be prepared. For the fabrication of the buildup layers 26 and 27, as depicted in FIG. 3, a resin sheet 41 is prepared. In the resin sheet 41, a glass fiber cloth is embedded in a resin material. The fiber of the glass fiber cloth extends along the front surface and the back surface of the resin sheet 41. When the resin sheet 41 is formed, the glass fiber cloth is impregnated with epoxy resin. The conductive wiring layer 29 is attached to the back surface of the resin sheet 41. Heating treatment is performed on the resin sheet 41. As a result, the epoxy resin is completely hardened in the resin sheet 41. The resin sheet 41 may be regarded as the insulating layer 28.

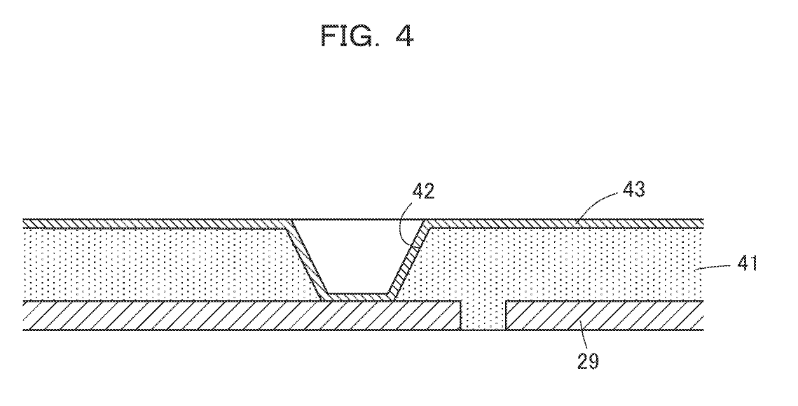

As depicted in FIG. 4, a through-hole 42 is formed at a predetermined position in the resin sheet 41. The through-hole 42 may be formed, for example, by a laser drill method. The through-hole 42 penetrates through the resin sheet 41. Thus, the glass fiber cloth of the resin sheet 41 may be exposed in the through-hole 42. The through-hole 42 partitions a space on the conductive wiring layer 29. After the formation of the through-hole 42, desmear process is performed on the front surface of the resin sheet 41. In the desmear process, sodium permanganate or potassium permanganate may be employed. Accordingly, smear in the through-hole 42 may be removed. Incidentally, a roughening process unlevels the front surface of the resin sheet 41 within a through-hole 42.

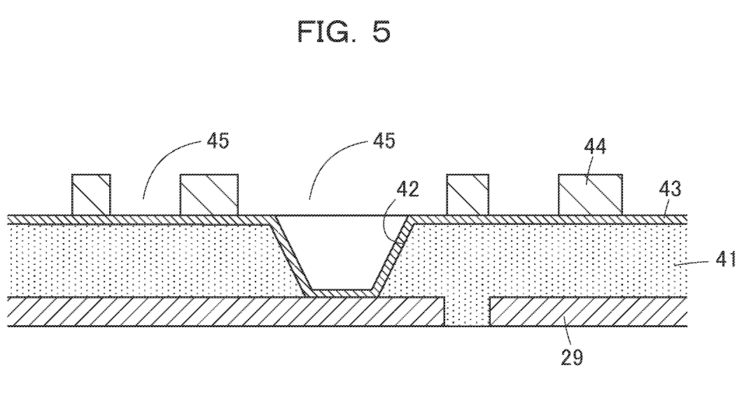

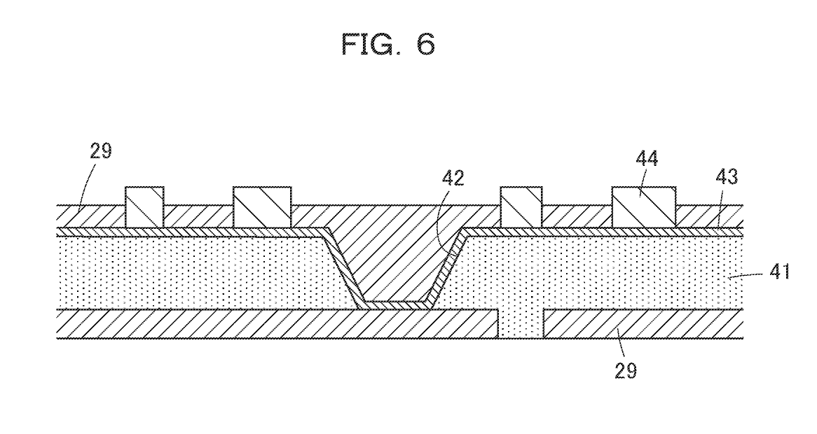

Then, an electroless deposition is performed on the front surface of the resin sheet 41 to create a seed layer 43 of conductive material. The seed layer 43 extends into the through-hole 42. Thereafter, as depicted in FIG. 5, a photoresist 44 with a predetermined pattern is formed on the seed layer 43. The photoresist 44 defines a void 45 in a predetermined pattern on the front surface of the resin sheet 41. The through-hole 42 is arranged within the void 45. As depicted in FIG. 6, an electrolytic plating of conductive material is performed on the front surface of the resin sheet 41. Thereafter, the photoresist 44 is removed. After the removal of the photoresist 44, the exposed seed layer 43 within the removal regions of the photoresist 44 is also removed by etching on the front surface of the resin sheet 41. In this way, the conductive pattern 29 is formed on the front surface of the resin sheet 41. Incidentally, the via 31 is formed in the through-hole 42.

After the removal of the photoresist 44, another resin sheet 41 is stacked on the front surface of the resin sheet 41. The conductive wiring layer 29 is sandwiched between the resin sheets 41 and 41. The resin sheet 41 is subjected to a heating treatment, and is stuck on the front surface of the resin sheet 41. Thereafter, the formation of the through-hole 42, the electroless plating, the deposition of the photoresist 44, the electrolytic plating, and the removal of the photoresist 44 are similarly repeated. In this way, the insulation layers 28 and the conductive wiring layers 29 in prescribed numbers of stacked layers are formed. The uppermost layer of the insulation layers 28 is provided with conductive pads 32 and the overcoat layer 33. In this way, the manufacture of the buildup layers 26 and 27 are completed.

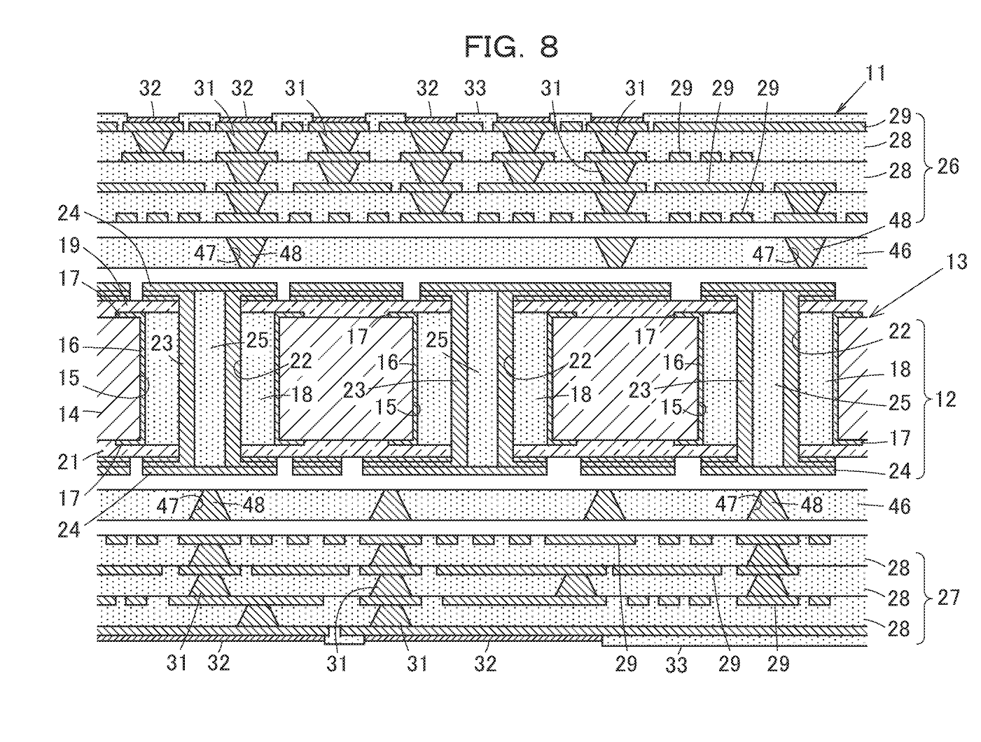

Thereafter, the buildup layers 26 and 27 are stacked on the front surface and the back surface of the core substrate 12. As depicted in FIG. 8, adhesion sheets 46 are stuck on the front surface and the back surface of the core substrate 12. The buildup layers 26 and 27 are stuck on the adhesion sheets 46. The adhesion sheet 46 is formed of heat-curable resin such as epoxy resin. A glass fiber cloth may be embedded in the adhesion sheet 46.

In the adhesion sheet 46, a through-hole 47 is formed between the conductive wiring layer 29 and the conductive land 24 of the core substrate 12. The through-hole 47 penetrates through the adhesion sheet 46. The conductive wiring layer 29 and the conductive land 24 face each other through the through-hole 47. The shape of the through-hole 47 may be set in accordance with those of the conductive wiring layer 29 and the conductive land 24. The through-hole 47 is filled with a conductive joint material 48. A screen printing method, for example, may be used for filling by the conductive joint material 48.

A heating process is performed on the laminated body of the core substrate 12, the adhesion sheets 46 and 46, and the buildup layers 26 and 27. A pressure is applied during heating in a direction perpendicular to the front surface and the back surface of the core substrate 12. As a result, the degree of adhesion of the core substrate 12, the adhesion sheets 46 and 46, and the buildup layers 26 and 27, is increased. With an increasing temperature, the adhesion sheet 46 is softened, and the shape of the adhesion sheet 46 is accommodated to the shape of the core substrate 12. Therefore, irregularities on the front surface of the core substrate 12 and those on the front surface of the laminated body may be covered in the adhesion sheet 46. After the heating is finished, the adhesion sheet 46 is hardened. The adhesion sheet 46 forms the insulating body 35 of the joint layer 34 as depicted in FIG. 1. When hardening of the adhesion sheet 46 is finished, the buildup layers 26 and 27 are joined on the front surface and the back surface of the core substrate 12, respectively. The printed wiring board 11 is released from heating and pressurization. In this way, the manufacture of the buildup printed circuit board 11 is completed.

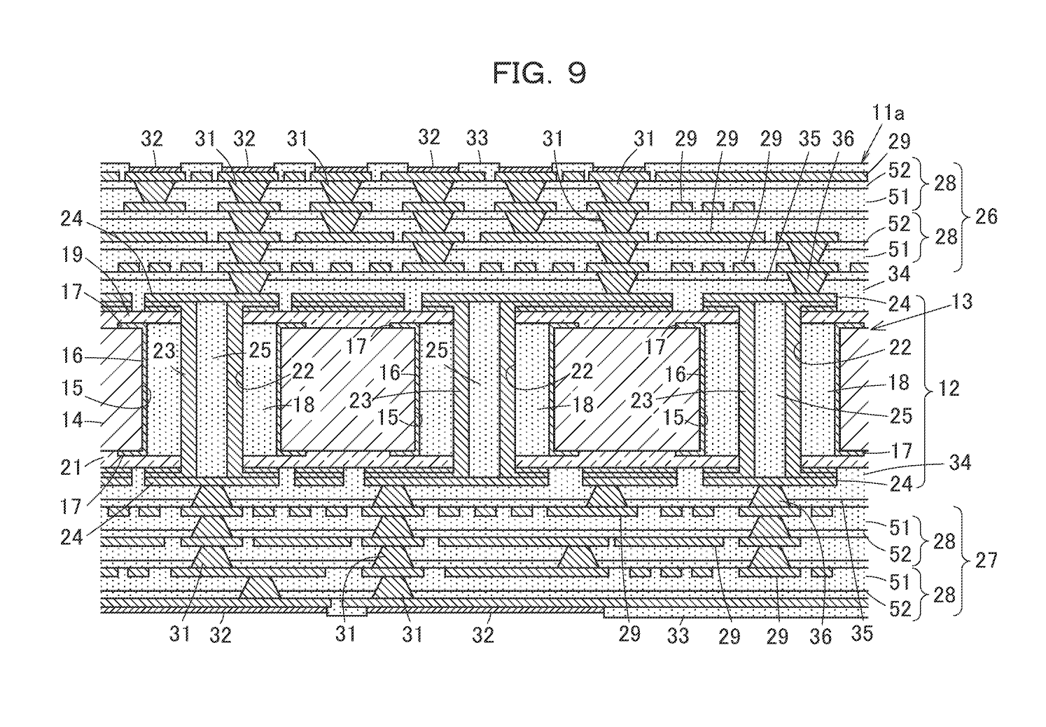

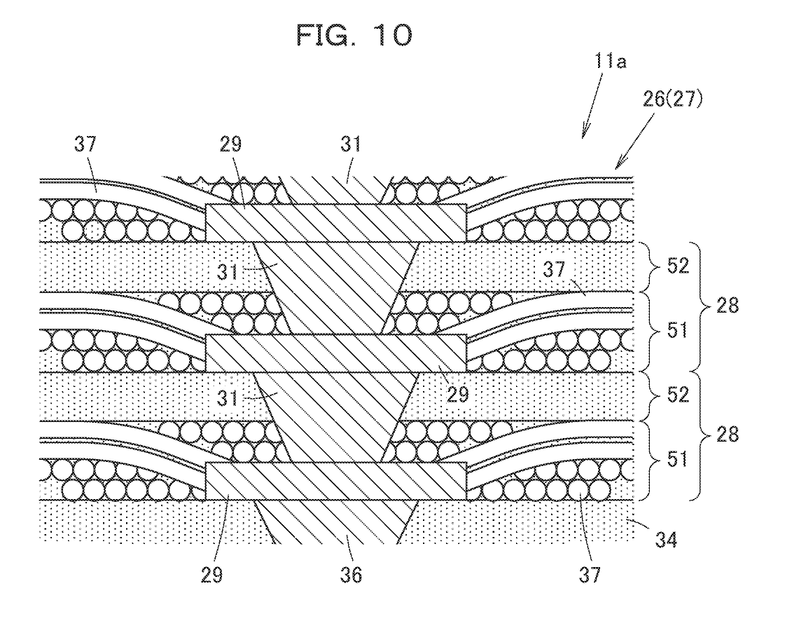

FIG. 9 schematically illustrates the cross-sectional structure of a printed wiring board 11a according to a second embodiment of the present invention. In the printed wiring board 11a, each of the insulating layers 28 is formed from a first insulating member 51 and a second insulating member 52 which are alternately stacked. As depicted in FIG. 10, the glass fiber cloth 37 is embedded in the first insulating member 51. The fiber of the glass fiber cloth 37 extends along the front surface of the first insulating member 51. When the first insulating member 51 is formed, the glass fiber cloth 37 is impregnated with resin material. The second insulating member 52 is formed of a resin material. The second insulating member 52 has no fiber cloth embedded therein. Heat-curable resin such as epoxy resin is used as the resin material. The first insulating member 51 has a greater thickness than the second insulating member 52. In addition, the same reference numerals are attached to equivalent components or structures as those of the printed wiring board 11 according to the first embodiment.

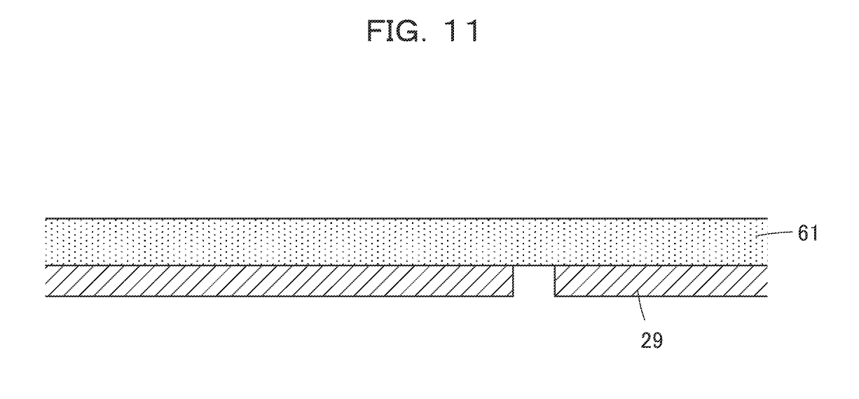

Next, the manufacturing method of the printed wiring board 11a will be described. The core substrate 12 is prepared. Also, the buildup layers 26 and 27 are prepared. For the fabrication of the buildup layers 26 and 27, as depicted in FIG. 11, a first resin sheet 61 is prepared. In the first resin sheet 61, a glass fiber cloth is embedded in a resin material. The fiber of the glass fiber cloth extends along the front surface and the back surface of the first resin sheet 61. When the first resin sheet 61 is formed, the glass fiber cloth is impregnated with epoxy resin. The conductive wiring layer 29 is stuck on the rear surface of the first resin sheet 61. A heating process is performed for the first resin sheet 61. At this time, the temperature of the heating process is set such that the epoxy resin is not completely hardened. As a result, the epoxy resin is semi-hardened in the first resin sheet 61. The first resin sheet 61 may be regarded as the first insulating member 51.

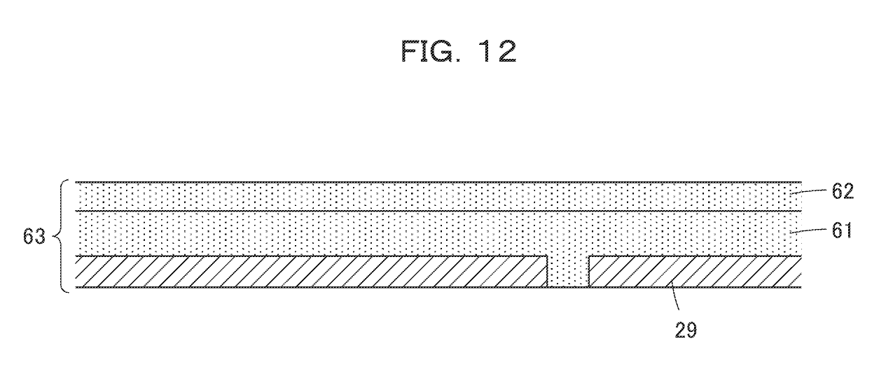

As depicted in FIG. 12, a second resin sheet 62 is stacked on the first resin sheet 61. The second resin sheet 62 is formed of an epoxy resin. Glass fiber cloth is not embedded in the second resin sheet 62. A heating process is performed in a state where the second resin sheet 62 is stacked on the front surface of the first resin sheet 61. The temperature of the heating process is set such that the epoxy resins of the first resin sheet 61 and the second resin sheet 62 are completely hardened. Therefore, the epoxy resin of the first resin sheet 61 and the second resin sheet 62 is completely hardened. A laminated body 63 of the first resin sheet 61 and the second resin sheet 62 is formed. The second resin sheet 62 may be regarded as the second insulating member 52. The laminated body 63 may be regarded as the insulating layer 28.

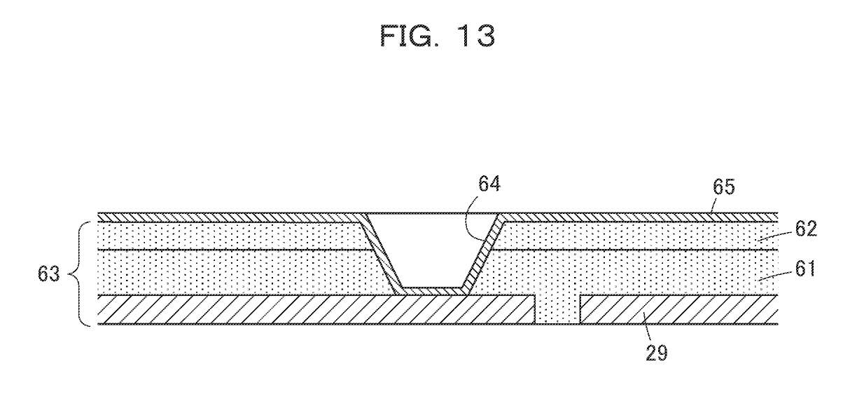

As depicted in FIG. 13, the laminated body 63 is provided with the through-hole 64 at a predetermined position. The through-hole 64 may be formed, for example, by a laser drill method. The through-hole 64 penetrates through the laminated body 63. The through-hole 64 defines a space on the conductive wiring layer 29. After the formation of the through-hole 64, a desmear process is performed on the front surface of the laminated body 63 so that smear in the through-hole 64 is eliminated. In the desmear process, sodium permanganate or potassium permanganate may be employed. Incidentally, a roughening process unlevels the front surface of the first resin sheet 61 and the front surface of the second resin sheet 62. In the through-hole 64, the glass fiber cloth of the first resin sheet 61 is exposed due to the melting of the resin material.

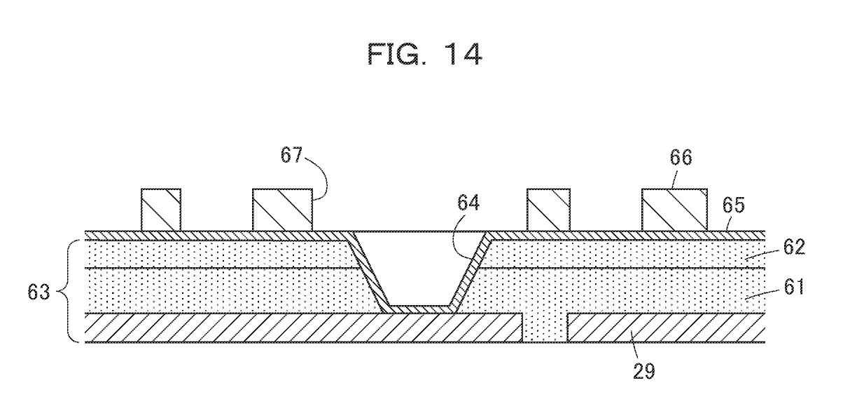

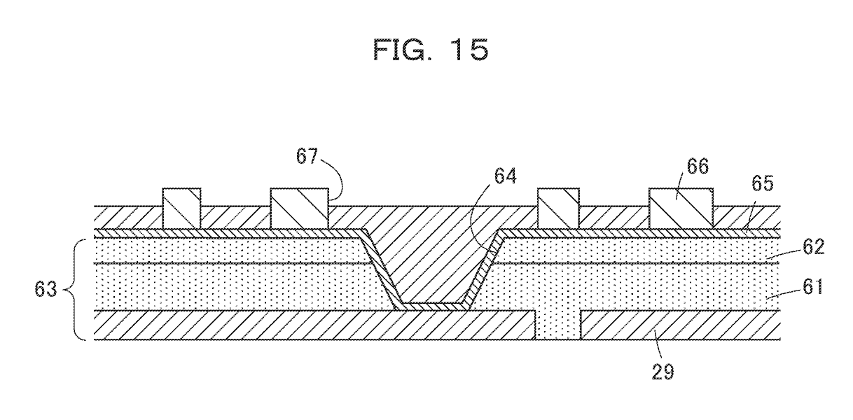

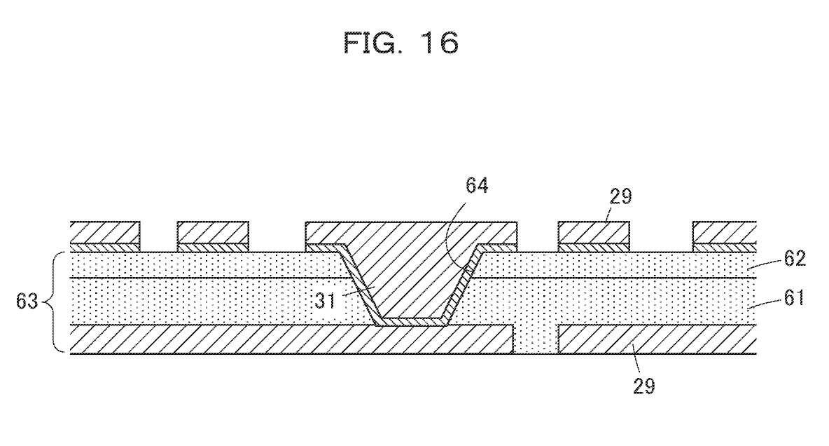

Then, an electroless deposition is performed on the front surface of the laminated body 63 to create a seed layer 65 of conductive material. The seed layer 65 extends into the through-hole 64. Thereafter, as depicted in FIG. 14, a photoresist 66 with a predetermined pattern is formed on the seed layer 65. The photoresist 66 defines a void 67 in a predetermined pattern on the front surface of the laminated body 63. The through-hole 64 is arranged within the void 67. As depicted in FIG. 15, an electrolytic plating of conductive material is performed on the front surface of the laminated body 63. Thereafter, the photoresist 66 is removed. After the removal of the photoresist 66, the exposed seed layer 65 within the removal regions of the photoresist 66 is also removed by etching on the front surface of the laminated body 63. In this manner, as depicted in FIG. 16, the conductive wiring layer 29 as described above is formed on the front surface of the laminated body 63. Incidentally, the via 31 is formed in the through-hole 64.

After the removal of the photoresist 66, another first resin sheet 61 is stacked on the front surface of the laminated body 63. The conductive wiring layer 29 is sandwiched between the laminated body 63 and the first resin sheet 61. The first resin sheet 61 is subjected to a heating process, and is stuck on the front surface of the laminated body 63. Thereafter, the stacking and heating process of the second resin sheet 62, the formation of the through-hole 64, the electroless plating, the deposition of the photoresist 66, the electrolytic plating, and the removal of the photoresist 66 are similarly repeated. In this way, the insulation layers 28 and the conductive wiring layers 29 in prescribed numbers of stacked layers are formed. The uppermost layer of the laminated body 63 is provided with conductive pads 32 and the overcoat layer 33. In this manner, the buildup layers 26 and 27 are formed, and the fabricated buildup layers 26 and 27 are stuck on the core substrate 12. In this manner, the manufacture of the buildup printed circuit board 11a is completed.

According to an embodiment of the printed wiring board 11a, the glass fiber cloth 37 is embedded in the insulation layer 28 of the buildup layers 26 and 27. As a result, the thermal expansion coefficient of the buildup layers 26 and 27 is suppressed to be low. The thermal expansion coefficient of the buildup layers 26 and 27 is accommodated to that of the core substrate 12, whereby the occurrence of a stress within the buildup layers 26 and 27 may be suppressed. Cracks in the buildup layers 26 and 27 may be suppressed. Consequently, a wiring disconnection in the conductive wiring layer 29 may be suppressed.

With the buildup layers 26 and 27 according to the foregoing embodiment, the plating solution flows into the through-hole 64 when the via 31 is formed. Since the glass fiber cloth is exposed into the through-hole 64, the plating solution may soak into the first resin sheet 61 along the interface between the resin material and the fibers of the glass fiber cloth. However, according to an embodiment of the printed wiring board, the second resin sheet 62 may be stacked on the first resin sheet 61. As a result, the glass fiber cloth may be reliably prevented from being exposed from the front surface of the insulation layer 28, that is, the front surface of the second resin sheet 62. Accordingly, even if the plating solution soaks along the interface between the resin material and the fibers, the plating solution may be prevented from reaching the front surface of the second resin sheet 62. Consequently, the via 31 may be prevented from being electrically connected to the conductive wiring layer 29

On the other hand, in a case where the glass fiber cloth 37 is adjacently embedded to the front surface of the insulation layer 28, the glass fiber cloth 37 may be exposed with respect to the insulation layer 28. On this occasion, when the above-described plating solution flows into the through-hole 64, the plating solution may soak into the insulation layer 28 along the interface between the resin material and the fibers of the glass fiber cloth 37. Due to this, the via 31 may be connected to the conductive wiring layer 29 through the plating solution. As a result, the via 31 may be electrically connected to the conductive wiring layer 29, and an abnormality may occur in the conductive pattern. Such a buildup layers 26, 27 would be unusable.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

1. A printed wiring board comprising:
a core substrate containing carbon fiber; and
a plurality of buildup layers stacked on the core substrate, the buildup layer including an insulating layer and a conductive wiring layer, the insulating layer containing a resin material having a glass fiber cloth embedded therein.

2. The printed wiring board according to claim 1, wherein the glass fiber cloth extends along the front surface of the insulating layer.

3. The printed wiring board according to claim 1, wherein the glass fiber cloth includes one of woven fabric and nonwoven fabric.

4. The printed wiring board according to claim 1, wherein the glass fiber cloth is completely embedded within the resin material.

5. The printed wiring board according to claim 1, wherein the insulating layer includes a first insulating member and a second insulating member which are alternately stacked, the glass fiber cloth being embedded in the first insulating member, the second insulating member having no fiber embedded therein.

6. The printed wiring board according to claim 5, wherein the glass fiber cloth extends along the front surface of the first insulating member.

7. The printed wiring board according to claim 5, wherein the first insulating member has a greater thickness than the second insulating member.
